(19) United States
(12) Patent Application Publication
(10) Pub. No.: US 2025/0159958 A1
(43) Pub. Date: May 15, 2025

(54) NITRIDE STRUCTURE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryoma KANEKO, Ota (JP); Hisashi YOSHIDA, Kawasaki (JP); Jumpei TAJIMA, Mitaka (JP); Shinya NUNOUE, Ichikawa (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/665,718

(22) Filed: May 16, 2024

(30) Foreign Application Priority Data
Nov. 10, 2023 (JP) 2023-192290

(51) Int. Cl. H01L 29/20; H01L 29/778

(52) U.S. Cl. CPC H10D 62/8503; H10D 30/475

(57) ABSTRACT

According to one embodiment, a nitride structure includes a first stacked body, a second stacked body, and an intermediate layer provided between the first stacked body and the second stacked body in a first direction and including Al_{z1}Ga_{1-z1}N (0≤z1≤1). The first stacked body includes a plurality of first films including Alₓ₁Ga₁₋ₓ₁N (0<x1≤1), and a plurality of second films including Alₓ₂Ga₁₋ₓ₂N (0≤x2<1, x2<x1). The second stacked body includes a plurality of third films including Alₓ₃Ga₁₋ₓ₃N (0<x3≤1), and a plurality of fourth films including Alₓ₄Ga₁₋ₓ₄N (0≤x4<1, x4<x3). The first stacked body includes a plurality of pits. A part of the intermediate layer is provided in the plurality of pits.

### CROSS-REFERENCE TO RELATED APPLICATIONS

This application is based upon and claims the benefit of priority from Japanese Patent Application No. 2023-192290, filed on Nov. 10, 2023; the entire contents of which are incorporated herein by reference.

### FIELD

Embodiments described herein relate generally to a nitride structure and a semiconductor device.

### BACKGROUND

For example, improved characteristics are desired in semiconductor devices based on nitride structures.

### BRIEF DESCRIPTION OF THE DRAWINGS

FIG. 1 is a schematic cross-sectional view illustrating a nitride structure according to a first embodiment;

FIG. 2 is a schematic cross-sectional view illustrating a nitride structure according to the first embodiment;

FIG. 3 is a schematic cross-sectional view illustrating a semiconductor device according to a second embodiment; and

FIG. 4 is a schematic cross-sectional view illustrating a semiconductor device according to the second embodiment.

### DETAILED DESCRIPTION

According to one embodiment, a nitride structure includes a first stacked body, a second stacked body, and an intermediate layer provided between the first stacked body and the second stacked body in a first direction and including Al_{z1}Ga_{1-z1}N (0≤z1≤1). The first stacked body includes a plurality of first films including Alₓ₁Ga₁₋ₓ₁N (0<x1≤1), and a plurality of second films including Alₓ₂Ga₁₋ₓ₂N (0≤x2<1, x2<x1). One of the plurality of first films is provided between one of the plurality of second films and another one of the plurality of second films in the first direction. The one of the plurality of second films is provided between the one of the plurality of first films and another one of the plurality of first films in the first direction. The second stacked body includes a plurality of third films including Alₓ₃Ga₁₋ₓ₃N (0<x3≤1), and a plurality of fourth films including Alₓ₄Ga₁₋ₓ₄N (0≤x4<1, x4<x3). One of the plurality of third films is provided between one of the plurality of fourth films and another one of the plurality of fourth films in the first direction. The one of the plurality of fourth films is provided between the one of the plurality of third films and another one of the plurality of third films in the first direction. The first stacked body includes a plurality of pits. A part of the intermediate layer is provided in the plurality of pits. The second stacked body does not include the pits. Or, a second density of the pits in the second stacked body is lower than a first density of the plurality of pits in the first stacked body.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

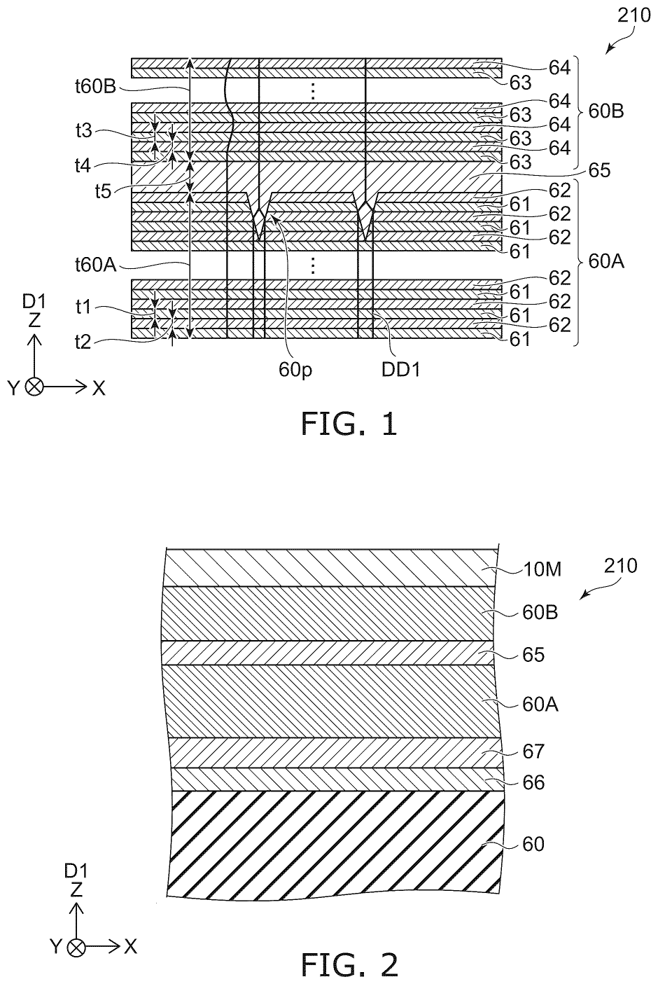

FIG. 1 is a schematic cross-sectional view illustrating a nitride structure according to the first embodiment.

As shown in FIG. 1, a nitride structure 210 according to the embodiment includes a first stacked body 60A, a second stacked body 60B, and an intermediate layer 65. The intermediate layer 65 is provided between the first stacked body 60A and the second stacked body 60B in a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The first stacked body 60A, the second stacked body 60B, and the intermediate layer 65 are in a layer form along the X-Y plane.

The intermediate layer 65 includes Al_{z1}Ga_{1-z1}N (0≤z1≤1). In one example, the composition ratio z1 is not less than 0 and not more than 0.30. The composition ratio z1 may be not less than and not more than 0.05. Intermediate layer 65 may include, for example, GaN. The intermediate layer 65 does not need to include, for example, an impurity that imparts conductivity.

The first stacked body 60A includes a plurality of first films 61 and a plurality of second films 62. For example, the plurality of first films 61 are arranged along the first direction D1. For example, the plurality of second films 62 are arranged along the first direction D1. The plurality of first films 61 include Alₓ₁Ga₁₋ₓ₁N (0<x1≤1). The plurality of second films 62 include Alₓ₂Ga₁₋ₓ₂N (0≤x2<1, x2<x1). In one example, the plurality of first films 61 may be AlN films. The plurality of second films 62 may be AlGaN films.

One of the plurality of first films 61 is provided between one of the plurality of second films 62 and another one of the plurality of second films 62 in the first direction D1. One of the plurality of second films 62 is provided between one of the plurality of first films 61 and another one of the plurality of first films 61 in the first direction D1. For example, the first film 61 and the second film 62 may be arranged alternately along the first direction D1. The first stacked body 60A is, for example, a superlattice layer.

The second stacked body 60B includes a plurality of third films 63 and a plurality of fourth films 64. For example, the plurality of third films 63 are arranged along the first direction D1. For example, the plurality of fourth films 64 are arranged along the first direction D1. The plurality of third films 63 include Alₓ₃Ga₁₋ₓ₃N (0<x3≤1). The plurality of fourth films 64 include Alₓ₄Ga₁₋ₓ₄N (0≤x4<1, x4<x3). In one example, the plurality of third films 63 may be AlN films. The plurality of fourth films 64 may be AlGaN films.

One of the plurality of third films 63 is provided between one of the plurality of fourth films 64 and another one of the plurality of fourth films 64 in the first direction D1. One of the plurality of fourth films 64 is provided between one of the plurality of third films 63 and another one of the plurality of third films 63 in the first direction D1. For example, the third film 63 and the fourth film 64 may be arranged alternately along the first direction D1. The second stacked body 60B is, for example, a superlattice layer.

As shown in FIG. 1, the first stacked body 60A includes a plurality of pits 60p. A portion of the intermediate layer 65 is provided within the plurality of pits 60p. The plurality of pits 60p are filled with intermediate layer 65. The intermediate layer 65 includes a surface facing second stacked body 60B. This surface may be substantially flat.

In the embodiment, the second stacked body 60B does not include pits. Alternatively, a second density of pits in the second stacked body 60B is lower than a first density of the plurality of pits 60p in the first stacked body 60A. With such a configuration, good crystallinity can be obtained in the second stacked body 60B. According to the embodiments, a nitride structure with improved properties is obtained.

As shown in FIG. 1, the first stacked body 60A includes a plurality of dislocations DD1. At least two of the plurality of dislocations DD1 coalesce in one of the plurality of pits 60p. This reduces the density of dislocations DD1. For example, the second dislocation density in the second stacked body 60B is lower than the first dislocation density in the first stacked body 60A.

In the embodiment, the plurality of pits 60p are intentionally introduced in the first stacked body 60A. The direction of the dislocation DD1 included in the first stacked body 60A changes in the pit 60p. Due to the change in direction, the plurality of dislocations DD1 coalesce. As a result, dislocation density can be reduced.

For example, the first stacked body 60A may be formed under conditions that facilitate the formation of the plurality of pits 60p. For example, when forming the first stacked body 60A, the V/III ratio of the source gas is set low, making it easier to form the plurality of pits 60p. For example, the temperature in the forming the first stacked body 60A may be set low. As a result, the plurality of pits 60p are likely to be formed. By forming the plurality of pits 60p, dislocation density can be reduced.

On the other hand, in the second stacked body 60B where the dislocation density is reduced, the plurality of pits 60p may be formed under conditions that make it difficult to form. A highly flat surface can be obtained.

In general, the pits 60p are recognized as crystal defects, and the aim is to suppress the formation of the pits 60p. On the other hand, in the embodiment, the effect of reducing dislocations in the plurality of pits 60p in the first stacked body 60A is utilized. The plurality of pits 60p are filled with the intermediate layer 65 and planarized. Furthermore, the second stacked body 60B is formed on the intermediate layer 65 in which dislocations are reduced under conditions that make it difficult for pits 60p to be formed. Thereby, low dislocation density and high flatness can be obtained in the second stacked body 60B.

For example, the second density of the plurality of pits 60p in the second stacked body 60B may be 0.5 times or less than the first density of the plurality of pits 60p in the first stacked body 60A.

For example, the second dislocation density in the second stacked body 60B is 0.5 times or less than the first dislocation density in the first stacked body 60A.

As shown in FIG. 1, an intermediate layer thickness t5 of the intermediate layer 65 along the first direction D1 is thicker than a first thickness t1 of one of the plurality of first films 61. The intermediate layer thickness t5 is thicker than a second thickness t2 of one of the plurality of second films 62. The intermediate layer thickness t5 is thicker than a third thickness t3 of one of the plurality of third films 63. The intermediate layer thickness t5 is thicker than a fourth thickness t4 of one of the plurality of fourth films 64.

For example, the intermediate layer thickness t5 may be not less than 10 times and not more than 300 times the first thickness t1. The intermediate layer thickness t5 may be not less than 2 times and not more than 60 times the second thickness t2. The intermediate layer thickness t5 may be not less than 10 times and not more than 300 times the third thickness t3. The intermediate layer thickness t5 may be not less than 2 times and not more than 60 times the fourth thickness t4.

For example, the composition ratio x1 is not less than 0.7 and not more than 1.0. At this time, the first thickness t1 may be not less than 3 nm and not more than 5 nm. For example, the composition ratio x2 is not less than 0.10 and not more than 0.50. At this time, the second thickness t2 may be not less than 5 nm and not more than 25 nm. For example, the composition ratio x3 is not less than 0.7 and not more than 1.0. At this time, the third thickness t3 may be not less than 3 nm and not more than 5 nm. For example, the composition ratio x4 is not less than 0.0 and not more than 0.30. At this time, the fourth thickness t4 may be not less than 5 nm and not more than 25 nm.

The thickness t60A (see FIG. 1) of the first stacked body 60A may be, for example, not less than 100 nm and not more than 1000 nm. The number of the plurality of first films 61 may be, for example, not less than 5 and not more than 125.

The thickness t60B (see FIG. 1) of the second stacked body 60B may be, for example, not less than 600 nm and not less than 3500 nm. The number of the plurality of third films 63 may be, for example, not less than 20 and not more than 435.

In the embodiment, a concentration of carbon in the first stacked body 60A may be higher than a concentration of carbon in the second stacked body 60B. For example, the first stacked body 60A is formed under conditions (for example, V/III ratio or temperature) that increase the carbon concentration. As a result, crystal defects such as the pits 60p are likely to be formed. In crystal defects, the direction of dislocations changes and the dislocation density can be reduced.

In the embodiment, the concentration of carbon in the first stacked body 60A may be not less than 2 times and not more than 10 times the concentration of carbon in the second stacked body 60B. The dislocation density can be effectively suppressed.

In the embodiment, a concentration of carbon in the intermediate layer 65 may be not less than 2 times and not more than 50 times the concentration of carbon in the second stacked body 60B. For example, high flatness can be obtained. For example, it becomes easy to obtain a high breakdown voltage.

FIG. 2 is a schematic cross-sectional view illustrating a nitride structure according to the first embodiment.

As shown in FIG. 2, the nitride structure 210 according to the embodiment may include a base 60, a first nitride layer 66, and a second nitride layer 67, in addition to the first stacked body 60A, the second stacked body 60B, and then intermediate layer 65.

The base 60 may be, for example, a silicon substrate. The first nitride layer 66 includes Al_{y1}Ga_{1-y1}N (0<y1≤1). The second nitride layer 67 includes Al_{y2}Ga_{1-y2}N (0<y2<1, y2<y1). The first nitride layer 66 is provided between the base 60 and the first stacked body 60A. The second nitride layer 67 is provided between the first nitride layer 66 and the first stacked body 60A.

The first nitride layer 66 and the second nitride layer 67 are, for example, buffer layers. For example, the first nitride layer 66 may include AlN. The first nitride layer 66 may be in contact with base 60. The second nitride layer 67 may be, for example, an AlGaN layer. By providing the buffer layer, it becomes easy to obtain high quality crystals.

The nitride structure 210 may include a semiconductor member 10M. The semiconductor member 10M includes, for example, Ga and N. The semiconductor member 10M may include, for example, a GaN layer and an AlGaN layer. The GaN layer is provided between the second stacked body 60B and the AlGaN layer.

### Second Embodiment

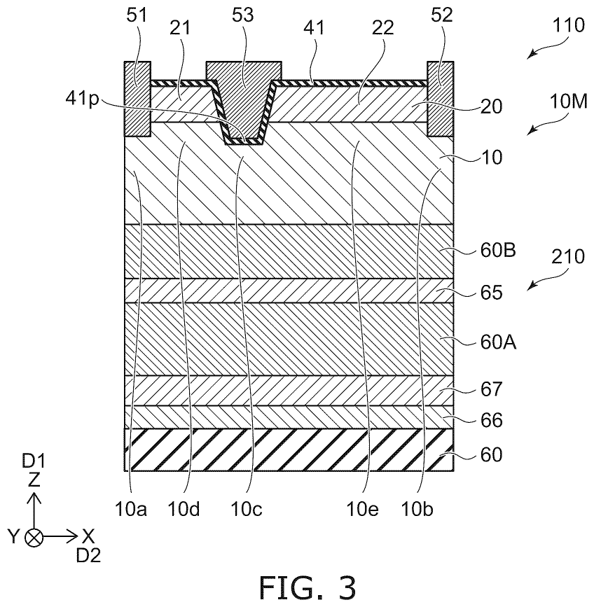

FIG. 3 is a schematic cross-sectional view illustrating a semiconductor device according to the second embodiment.

As shown in FIG. 3, a semiconductor device 110 according to the embodiment includes the nitride structure 210 according to the first embodiment, the semiconductor member 10M, a first electrode 51, a second electrode 52, and a third electrode 53. The semiconductor member 10M includes a first semiconductor layer 10 including Al_{α1}Ga_{1-α1}N (0≤α1<1) and a second semiconductor layer 20 including Al_{α2}Ga_{1-α2}N (0<α2≤1, α1<α2). The composition ratio α1 is, for example, not less than 0 and not more than 0.15. The first semiconductor layer 10 may be, for example, a GaN layer. The composition ratio α2 is, for example, more than 0.15 and not more than 0.3. The second semiconductor layer 20 may be, for example, an AlGaN layer.

The first semiconductor layer 10 is provided between the second stacked body 60B and the second semiconductor layer 20. The semiconductor member 10M may further include a nitride layer. The nitride layer is provided between the second stacked body 60B and the first semiconductor layer 10. The nitride layer is, for example, a GaN layer. A carbon concentration in the nitride layer is higher than a carbon concentration in the first semiconductor layer 10. The nitride layer may be provided as needed or may be omitted.

A second direction D2 from the first electrode 51 to the second electrode 52 crosses the first direction D1. The second direction D2 may be, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

A current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

The semiconductor device 110 includes the nitride structure 210 according to the first embodiment. Good crystallinity can be obtained in the semiconductor device 110. For example, lower dislocation densities are obtained.

As shown in FIG. 3, in this example, at least a part of the third electrode 53 is provided between the first semiconductor portion 21 and the second semiconductor portion 22 in the second direction D2. The third electrode 53 is, for example, a recessed gate electrode.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and a position of the second partial region 10b in the second direction D2.

A direction from the fourth partial region 10d to the first semiconductor portion 21 is along the first direction D1. The direction from the fifth partial region 10e to the second semiconductor portion 22 is along the first direction D1. In this example, a part of the third electrode 53 is located between the fourth partial region 10d and the fifth partial region 10e in the second direction D2. A high threshold voltage can be obtained. For example, normally-off operation is obtained.

As shown in FIG. 3, the semiconductor device 110 may further include a first insulating member 41. The first insulating member 41 includes a first insulating portion 41p. The first insulating portion 41p is provided between the third electrode 53 and the semiconductor member 10M. The first insulating portion 41p functions, for example, as a gate insulating film.

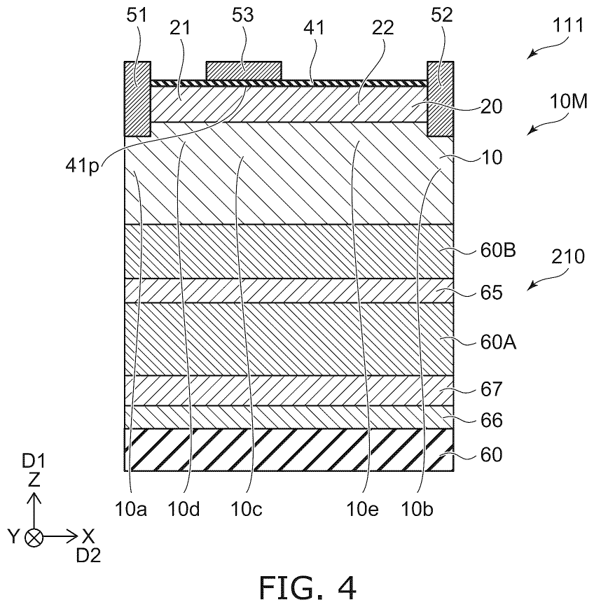

FIG. 4 is a schematic cross-sectional view illustrating a semiconductor device according to the second embodiment.

As shown in FIG. 4, a semiconductor device 111 according to the embodiment includes the nitride structure 210 according to the first embodiment, the semiconductor member 10M, the first electrode 51, the second electrode 52, and the third electrode 53. In the semiconductor device 111, the third electrode 53 does not overlap the second semiconductor layer 20 in the second direction D2. The configuration of the semiconductor device 111 except for this may be the same as that of the semiconductor device 110.

The semiconductor device 111 can obtain normally-on operation, for example. In the semiconductor device 111, the first insulating member 41 may be omitted. For example, the device may be used as a high frequency switching element.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by reciprocal space mapping.

Embodiments may include the following Technical proposals:

### (Technical Proposal 1)

A nitride structure, comprising:
a first stacked body;
a second stacked body; and
an intermediate layer provided between the first stacked body and the second stacked body in a first direction and including Al_{z1}Ga_{1-z1}N (0≤z1≤1),
the first stacked body including
   a plurality of first films including Alₓ₁Ga₁₋ₓ₁N (0<x1≤1), and
   a plurality of second films including Alₓ₂Ga₁₋ₓ₂N (0≤x2<1, x2<x1),
one of the plurality of first films being provided between one of the plurality of second films and another one of the plurality of second films in the first direction,
the one of the plurality of second films being provided between the one of the plurality of first films and another one of the plurality of first films in the first direction,
the second stacked body including
   a plurality of third films including Alₓ₃Ga₁₋ₓ₃N (0<x3≤1), and
   a plurality of fourth films including Alₓ₄Ga₁₋ₓ₄N (0≤x4<1, x4<x3),
one of the plurality of third films being provided between one of the plurality of fourth films and another one of the plurality of fourth films in the first direction,
the one of the plurality of fourth films being provided between the one of the plurality of third films and another one of the plurality of third films in the first direction,
the first stacked body including a plurality of pits,
a part of the intermediate layer being provided in the plurality of pits, and
the second stacked body not including the pits, or a second density of the pits in the second stacked body being lower than a first density of the plurality of pits in the first stacked body.

### (Technical Proposal 2)

The nitride structure according to Technical proposal 1, wherein
the second density is 0.5 times or less than the first density.

### (Technical Proposal 3)

The nitride structure according to Technical proposal 1 or 2, wherein
a second dislocation density in the second stacked body is lower than a first dislocation density in the first stacked body.

### (Technical Proposal 4)

The nitride structure according to any one of Technical proposals 1-3, wherein
an intermediate layer thickness of the intermediate layer along the first direction is thicker than a first thickness of the one of the plurality of first films,
the intermediate layer thickness is thicker than a second thickness of the one of the plurality of second films,
the intermediate layer thickness is thicker than a third thickness of the one of the plurality of third films, and
the intermediate layer thickness is thicker than a fourth thickness of the one the plurality of fourth films.

### (Technical Proposal 5)

The nitride structure according to Technical proposal 4, wherein
the intermediate layer thickness is not less than 10 times and not more than 300 times the first thickness.

### (Technical Proposal 6)

The nitride structure according to Technical proposal 4, wherein
the intermediate layer thickness is not less than 2 times and not more than 60 times the second thickness.

### (Technical Proposal 7)

The nitride structure according to Technical proposal 4, wherein
the intermediate layer thickness is not less than 10 times and not more than 300 times the third thickness.

### (Technical Proposal 8)

The nitride structure according to Technical proposal 4, wherein
the intermediate layer thickness is not less than 2 times and not more than 60 times the fourth thickness.

### (Technical Proposal 9)

The nitride structure according to any one of Technical proposals 4-8, wherein
the x1 is not less than 0.7 and not more than 1.0, and the first thickness is not less than 3 nm and not more than 5 nm,
the x2 is not less than 0.1 and not more than 0.5 or less, and the second thickness is not less than 5 nm and not more than 25 nm,
the x3 is not less than 0.7 and not more than 1.0, and the third thickness is not less than 3 nm and not more than 5 nm, and
the x4 is not less than 0.0 and not more than 0.3, and the fourth thickness is not less than 5 nm and not more than 25 nm.

### (Technical Proposal 10)

The nitride structure according to any one of Technical proposals 1-9, wherein
the z1 is not less than 0 and not more than 0.05.

### (Technical Proposal 11)

The nitride structure according to any one of Technical proposals 1-10, wherein
the first stacked body includes a plurality of dislocations, and
at least two of the plurality of dislocations coalesce in one of the plurality of pits.

### (Technical Proposal 12)

The nitride structure according to any one of Technical proposals 1-11, wherein
a concentration of carbon in the first stacked body is higher than a concentration of carbon in the second stacked body.

### (Technical Proposal 13)

The nitride structure according to Technical proposal 1, wherein
the concentration of carbon in the first stacked body is not more than 2 times and not more than 10 times the concentration of carbon in the second stacked body.

### (Technical Proposal 14)

A nitride structure, comprising:
a first stacked body;
a second stacked body; and
an intermediate layer provided between the first stacked body and the second stacked body in a first direction and including Al_{z1}Ga_{1-z1}N (0≤z1≤1),
the first stacked body including
   a plurality of first films including Alₓ₁Ga₁₋ₓ₁N (0<x1≤1), and
   a plurality of second films including Alₓ₂Ga₁₋ₓ₂N (0≤x2<1, x2<x1),
one of the plurality of first films being provided between one of the plurality of second films and another one of the plurality of second films in the first direction,
the one of the plurality of second films being provided between the one of the plurality of first films and another one of the plurality of first films in the first direction,
the second stacked body including
   a plurality of third films including Alₓ₃Ga₁₋ₓ₃N (0<x3≤1), and
   a plurality of fourth films including Alₓ₄Ga₁₋ₓ₄N (0≤x4<1, x4<x3),
one of the plurality of third films being provided between one of the plurality of fourth films and another one of the plurality of fourth films in the first direction,
the one of the plurality of fourth films being provided between the one of the plurality of third films and another one of the plurality of third films in the first direction, and
a concentration of carbon in the first stacked body being higher than a concentration of carbon in the second stacked body.

### (Technical Proposal 15)

The nitride structure according to Technical proposal 14, wherein
the concentration of carbon in the first stacked body is not more than 2 times and not more than 10 times the concentration of carbon in the second stacked body.

### (Technical Proposal 16)

The nitride structure according to any one of Technical proposals 1-15, further comprising:
a base;
a first nitride layer including Al_{y1}Ga_{1-y1}N (0<y1≤1); and
a second nitride layer including Al_{y2}Ga_{1-y2}N (0<y2<1, y2<y1),
the first nitride layer being provided between the base and the first laminate, and
the second nitride layer being provided between the first nitride layer and the first stacked body.

### (Technical Proposal 17)

The nitride structure according to Technical proposal 16, wherein
the first nitride layer includes AlN and is in contact with the base.

### (Technical Proposal 18)

A semiconductor device, comprising:
the nitride structure according to any one of Technical proposals 1-17;
a semiconductor member;
a first electrode;
a second electrode; and
a third electrode,
the semiconductor member including
   a first semiconductor layer including Al_{α1}Ga_{1-α1}N (0≤α1<1), and
   a second semiconductor layer including Al_{α2}Ga_{1-α2}N (0<α2≤1, α1<α2),
the first semiconductor layer being provided between the second stacked body and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

### (Technical Proposal 19)

The semiconductor device according to Technical proposal 18, further comprising:
a first insulating member including a first insulating portion, and
the first insulating portion being provided between the third electrode and the semiconductor member.

### (Technical Proposal 20)

The semiconductor device according to Technical proposal 18 or 19, wherein
at least a part of the third electrode is provided between the first semiconductor portion and the second semiconductor portion in the second direction.

According to the embodiment, a nitride structure and a semiconductor device with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

In the specification, “state of being electrically connected” includes a state in which a plurality of conductors are physically in contact with each other and a current flows between the plurality of conductors. The “state of being electrically connected” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the nitride structure such as nitride regions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nitride structures and all semiconductor devices practicable by an appropriate design modification by one skilled in the art based on the nitride structures and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride structure, comprising:
a first stacked body;
a second stacked body; and
an intermediate layer provided between the first stacked body and the second stacked body in a first direction and including Al_{z1}Ga_{1-z1}N (0≤z1≤1),
the first stacked body including
a plurality of first films including Alₓ₁Ga₁₋ₓ₁N (0<x1≤1), and
a plurality of second films including Alₓ₂Ga₁₋ₓ₂N (0≤x2<1, x2<x1),
one of the plurality of first films being provided between one of the plurality of second films and another one of the plurality of second films in the first direction,
the one of the plurality of second films being provided between the one of the plurality of first films and another one of the plurality of first films in the first direction,
the second stacked body including
a plurality of third films including Alₓ₃Ga₁₋ₓ₃N (0<x3≤1), and
a plurality of fourth films including Alₓ₄Ga₁₋ₓ₄N (0≤x4<1, x4<x3),
one of the plurality of third films being provided between one of the plurality of fourth films and another one of the plurality of fourth films in the first direction,
the one of the plurality of fourth films being provided between the one of the plurality of third films and another one of the plurality of third films in the first direction,
the first stacked body including a plurality of pits,
a part of the intermediate layer being provided in the plurality of pits, and
the second stacked body not including the pits, or a second density of the pits in the second stacked body being lower than a first density of the plurality of pits in the first stacked body.

2. The structure according to claim 1, wherein
the second density is 0.5 times or less than the first density.

3. The structure according to claim 1, wherein
a second dislocation density in the second stacked body is lower than a first dislocation density in the first stacked body.

4. The structure according to claim 1, wherein
an intermediate layer thickness of the intermediate layer along the first direction is thicker than a first thickness of the one of the plurality of first films,
the intermediate layer thickness is thicker than a second thickness of the one of the plurality of second films,
the intermediate layer thickness is thicker than a third thickness of the one of the plurality of third films, and
the intermediate layer thickness is thicker than a fourth thickness of the one the plurality of fourth films.

5. The structure according to claim 4, wherein
the intermediate layer thickness is not less than 10 times and not more than 300 times the first thickness.

6. The structure according to claim 4, wherein
the intermediate layer thickness is not less than 2 times and not more than 60 times the second thickness.

7. The structure according to claim 4, wherein
the intermediate layer thickness is not less than 10 times and not more than 300 times the third thickness.

8. The structure according to claim 4, wherein
the intermediate layer thickness is not less than 2 times and not more than 60 times the fourth thickness.

9. The structure according to claim 4, wherein
the x1 is not less than 0.7 and not more than 1.0, and the first thickness is not less than 3 nm and not more than 5 nm,
the x2 is not less than 0.1 and not more than 0.5 or less, and the second thickness is not less than 5 nm and not more than 25 nm,
the x3 is not less than 0.7 and not more than 1.0, and the third thickness is not less than 3 nm and not more than 5 nm, and
the x4 is not less than 0.0 and not more than 0.3, and the fourth thickness is not less than 5 nm and not more than 25 nm.

10. The structure according to claim 1, wherein
the z1 is not less than 0 and not more than 0.05.

11. The structure according to claim 1, wherein
the first stacked body includes a plurality of dislocations, and
at least two of the plurality of dislocations coalesce in one of the plurality of pits.

12. The structure according to claim 1, wherein
a concentration of carbon in the first stacked body is higher than a concentration of carbon in the second stacked body.

13. The structure according to claim 1, wherein
the concentration of carbon in the first stacked body is not more than 2 times and not more than 10 times the concentration of carbon in the second stacked body.

14. A nitride structure, comprising:
a first stacked body;
a second stacked body; and
an intermediate layer provided between the first stacked body and the second stacked body in a first direction and including Al_{z1}Ga_{1-z1}N (0≤z1≤1),
the first stacked body including
a plurality of first films including Alₓ₁Ga₁₋ₓ₁N (0<x1≤1), and
a plurality of second films including Alₓ₂Ga₁₋ₓ₂N (0≤x2<1, x2<x1),
one of the plurality of first films being provided between one of the plurality of second films and another one of the plurality of second films in the first direction,
the one of the plurality of second films being provided between the one of the plurality of first films and another one of the plurality of first films in the first direction,
the second stacked body including
a plurality of third films including Alₓ₃Ga₁₋ₓ₃N (0<x3≤1), and
a plurality of fourth films including Alₓ₄Ga₁₋ₓ₄N (0≤x4<1, x4<x3),
one of the plurality of third films being provided between one of the plurality of fourth films and another one of the plurality of fourth films in the first direction,
the one of the plurality of fourth films being provided between the one of the plurality of third films and another one of the plurality of third films in the first direction, and
a concentration of carbon in the first stacked body being higher than a concentration of carbon in the second stacked body.

15. The structure according to claim 14, wherein
the concentration of carbon in the first stacked body is not more than 2 times and not more than 10 times the concentration of carbon in the second stacked body.

16. The structure according to claim 1, further comprising:
a base;
a first nitride layer including Al_{y1}Ga_{1-y1}N (0<y1≤1); and
a second nitride layer including Al_{y2}Ga_{1-y2}N (0<y2<1, y2<y1),
the first nitride layer being provided between the base and the first laminate, and
the second nitride layer being provided between the first nitride layer and the first stacked body.

17. The structure according to claim 16, wherein
the first nitride layer includes AlN and is in contact with the base.

18. A semiconductor device, comprising:
the nitride structure according to claim 1;
a semiconductor member;
a first electrode;
a second electrode; and
a third electrode,
the semiconductor member including
a first semiconductor layer including Al_{α1}Ga_{1-α1}N (0≤α1<1), and
a second semiconductor layer including Al_{α2}Ga_{1-α2}N (0<α2≤1, α1<α2),
the first semiconductor layer being provided between the second stacked body and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

19. The device according to claim 18, further comprising:
a first insulating member including a first insulating portion, and
the first insulating portion being provided between the third electrode and the semiconductor member.

20. The device according to claim 18, wherein
at least a part of the third electrode is provided between the first semiconductor portion and the second semiconductor portion in the second direction.
